(19) United States
(12) Patent Application Publication
(10) Pub. No.: US 2023/0260497 A1
(43) Pub. Date: Aug. 17, 2023

(54) SOUND ABSORBING UNIT, SOUND ABSORBING STRUCTURE, MANUFACTURING METHOD, AND DESIGN METHOD

(71) Applicant: Pixie Dust Technologies, Inc., Tokyo (JP)

(72) Inventors: Yudai TAIRA, Tokyo (JP); Masaki GOMI, Tokyo (JP)

(73) Assignee: Pixie Dust Technologies, Inc., Tokyo (JP)

(21) Appl. No.: 18/303,055

(22) Filed: Apr. 19, 2023

Related U.S. Application Data
(63) Continuation of application No. PCT/JP2021/038718, filed on Oct. 20, 2021.

(30) Foreign Application Priority Data
Oct. 27, 2020 (JP) 2020-179481

(51) Int. Cl. G10K 11/172; G06F 30/10

(52) U.S. Cl. CPC G10K 11/172; G06F 30/10; G10K 11/04

(57) ABSTRACT

A sound absorbing unit includes: a perforated plate that is a plate member having a plurality of holes; a first cavity extending in a first direction, the first cavity allowing sound waves to enter through a plurality of holes present in a first region of the perforated plate; and a second cavity extending substantially parallel to the first direction, the second cavity allowing sound waves to enter through a plurality of holes present in a second region of the perforated plate. The first cavity and the second cavity are arranged in a second direction perpendicular to the first direction. A surface of the perforated plate is orthogonal to neither the first direction nor the second direction. The first cavity and the second cavity have different lengths in the first direction.

### CROSS-REFERENCE TO RELATED APPLICATIONS

This application is a Continuation Application of International Patent Application No. PCT/JP2021/38718, filed on Oct. 20, 2021, which is based upon and claims the benefit of priority from Japanese Patent Application No. 2020-179481, filed on Oct. 27, 2020, the entire contents of which are incorporated herein by reference.

### TECHNICAL FIELD

The present disclosure relates to sound absorbing units, sound absorbing structures, manufacturing methods, and design methods.

### BACKGROUND

Suppression of noise generated in railways, highways, construction sites, etc. is one of the important social issues. In particular, it is required to effectively absorb low-frequency noise.

Rui (2020) [Rui Liu, et al. “Ultra-broadband acoustic absorption of a thin microperforated panel metamaterial with multi-order resonance.” Composite Structures, 246 (2020) 112366] proposes an acoustic metamaterial in which Fabry-Perot resonators having different resonance frequencies are combined. The acoustic metamaterial of Rui (2020) is configured in a space-saving manner by folding a long (that is, a low resonance frequency) waveguide and arranging it in combination with a short (that is, a high resonance frequency) waveguide. Therefore, according to this acoustic metamaterial, while suppressing the thickness (dimension in the traveling direction of the sound wave to be sound-absorbed (in the example of Rui (2020), the direction perpendicular to the perforated plate (MPP: Micro-Perforated Panel))), can exhibit sound absorption characteristics according to the characteristics of waveguides of various lengths.

In the acoustic metamaterial of Rui (2020), waveguides of various shapes are arranged in a complicated manner. Therefore, the structure of the acoustic metamaterial of Rui (2020) is not suitable for mass production by, for example, injection molding, and cannot be said to have high manufacturability.

### BRIEF DESCRIPTION OF THE DRAWINGS

FIG. 1 is a perspective view showing a sound absorbing unit of this embodiment;

FIG. 2 is an HD cross-sectional view showing the sound absorbing unit of the present embodiment;

FIG. 3 is an explanatory diagram of the outline of the sound absorbing unit of the embodiment;

FIG. 4 is a diagram showing an example of a manufacturing outline of the sound absorbing unit of the present embodiment;

FIG. 5 is a diagram showing an example of a manufacturing outline of the sound absorbing unit of the present embodiment;

FIG. 6 is a diagram showing an example of a manufacturing outline of the sound absorbing unit of the present embodiment;

FIG. 7 is a diagram showing a sound absorbing structure using the sound absorbing unit of this embodiment;

FIG. 8 is an explanatory diagram of an outline of a sound absorbing structure using the sound absorbing unit of the present embodiment;

FIG. 9 is a perspective view of a support unit that supports the sound absorbing unit of this embodiment;

FIG. 10 is an explanatory diagram of support of the sound absorbing unit by the support unit of the present embodiment;

FIG. 11 is an HD cross-sectional view showing a sound absorbing unit of Modification 1;

FIG. 12 is an HD cross-sectional view showing a sound absorbing unit of Modification 2;

FIG. 13 is an explanatory diagram of support of the sound absorbing unit by the support unit of Modification 3;

FIG. 14 is a diagram illustrating an example of a design apparatus that executes design processing according to Modification 4; and

FIG. 15 is a diagram showing the overall flow of design processing of Modification 4.

### DETAILED DESCRIPTION

Hereinafter, an embodiment of the present disclosure is described in detail based on the drawings. Note that, in the drawings for describing the embodiments, the same components are denoted by the same reference sign in principle, and the repetitive description thereof is omitted.

According to an aspect of the present disclosure, a sound absorbing unit includes: a perforated plate that is a plate member having a plurality of holes; a first cavity extending in a first direction, the first cavity allowing sound waves to enter through a plurality of holes present in a first region of the perforated plate; and a second cavity extending substantially parallel to the first direction, the second cavity allowing sound waves to enter through a plurality of holes present in a second region of the perforated plate. The first cavity and the second cavity are arranged in a second direction perpendicular to the first direction. A surface of the perforated plate is orthogonal to neither the first direction nor the second direction. The first cavity and the second cavity have different lengths in the first direction.

In the following description, the “D direction” is the incident direction of sound waves with respect to the sound absorbing unit, and can also be called the thickness direction. “H direction” is the height direction of the sound absorbing unit. A waveguide included in the sound absorbing unit described below is a space (that is, a cavity) into which sound waves can enter, part or all of which extends along the H direction and functions as a resonator. The “W direction” is a direction orthogonal to the “D direction” and the “H direction” and can also be called the width direction.

### (1) Configuration of Sound Absorbing Unit

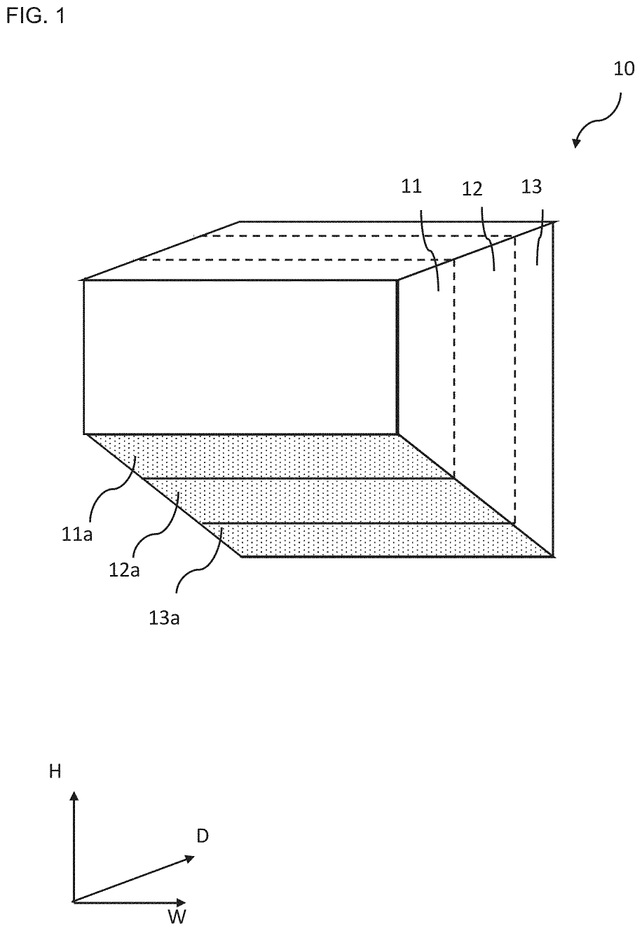

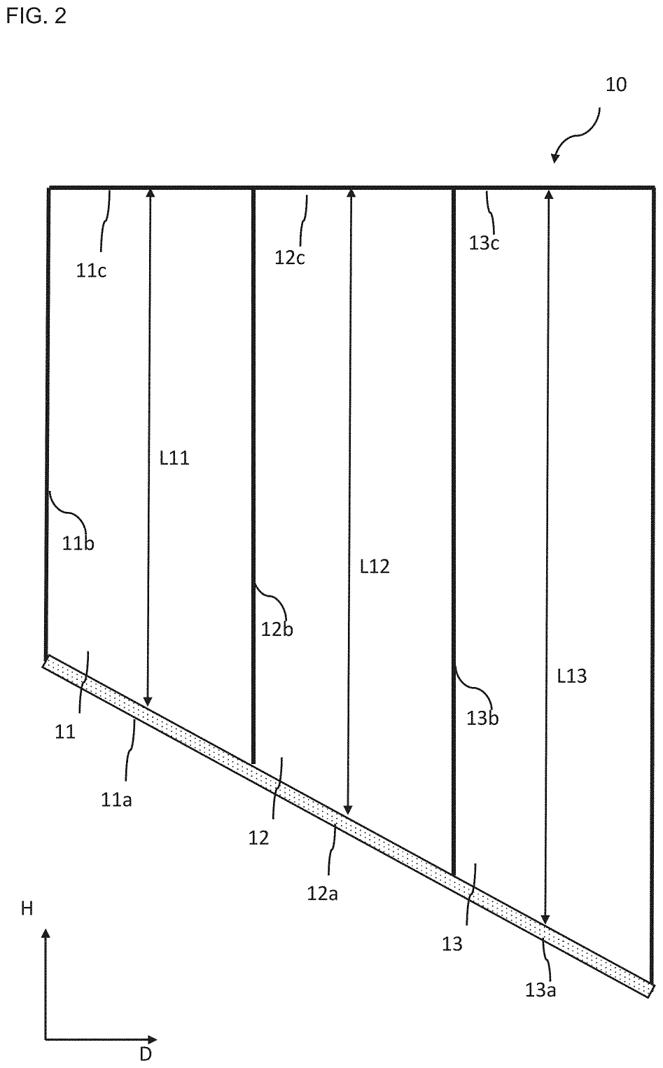

The configuration of the sound absorbing unit will be described. A sound absorbing unit is a member with a specific structure that has a sound absorbing effect of absorbing the energy of sound waves propagating toward the sound absorbing unit and reducing the sound pressure of reflected sound and transmitted sound. FIG. 1 is a perspective view showing the sound absorbing unit of this embodiment. FIG. 2 is an HD cross-sectional view showing the sound absorbing unit of this embodiment. As shown in FIGS. 1 and 2, the sound absorbing unit is a frustum, a perforated plate is provided on a surface different from the bottom surface of the frustum, and the interior of the sound absorbing unit is divided into a plurality of cavities by side walls. The details are described below.

As shown in FIG. 1, the sound absorbing unit 10 comprises a first waveguide 11, a second waveguide 12 and a third waveguide 13. The first to third waveguides 11 to 13 are laminated along the thickness direction (D direction).

As shown in FIG. 2, the first waveguide 11 has a first starting end, a first side wall 11b and a first terminal end 11c. The length of the first waveguide 11 is represented by L11.

The first starting end is provided with a first perforated plate 11a having a plurality of holes (an example of “first holes”) through which sound waves can be incident. The first perforated plate 11a corresponds to an acoustic impedance matching member.

A first side wall 11b connects the first starting end and the first terminal end 11c. In the example of FIG. 2, the HD section of the outline of the first side wall 11b is a rectangle whose longitudinal direction is parallel to the H direction, in other words, an I shape.

A reflecting wall capable of reflecting sound waves is provided at the first terminal end 11c.

As shown in FIG. 2, the second waveguide 12 has a second starting end, a second side wall 12b and a second terminal end 12c. The second waveguide 12 is laminated along the D direction with respect to the first waveguide 11. Specifically, the second waveguide 12 is arranged such that the second starting end is in contact with the first starting end, the second side wall 12b is in contact with the first side wall 11b, and the second terminal end 12c is in contact with the first terminal end 11c.

The length of the second waveguide 12 is represented by L12. The length of the second waveguide 12 is longer than the length of the first waveguide 11. That is, the second waveguide 12 can absorb sound waves in a frequency band different from that of the first waveguide 11.

A second perforated plate 12a having a plurality of holes (an example of a “second hole”) through which sound waves can enter is provided at the second starting end. The second perforated plate 12a corresponds to an acoustic impedance matching member.

A second side wall 12b connects the second starting end and the second terminal end 12c. In the example of FIG. 2, the HD section of the contour of the second side wall 12b is a rectangle whose longitudinal direction is parallel to the H direction, in other words, an I shape.

The second terminal end 12c is provided with a reflecting wall capable of reflecting sound waves.

As shown in FIG. 2, the third waveguide 13 has a third starting end, a third side wall 13b and a third terminal end 13c. The third waveguide 13 is laminated along the D direction with respect to the second waveguide 12. Specifically, the third waveguide 13 is arranged such that the third starting end is in contact with a second starting end, the third side wall 13b is in contact with a second side wall 12b, and the third terminal end 13c is in contact with a second side wall 12b.

The length of the third waveguide 13 is represented by L13. The length of the third waveguide 13 is longer than the length of the second waveguide 12. That is, the third waveguide 13 can absorb sound waves in a frequency band different from that of the second waveguide 12.

A third perforated plate 13a having a plurality of holes (an example of a “third hole”) through which sound waves can enter is provided at the third starting end. The third perforated plate 13a corresponds to an acoustic impedance matching member.

A third side wall 13b connects the third starting end and the third terminal end 13c. In the example of FIG. 2, the HD section of the contour of the third side wall 13b is a rectangle whose longitudinal direction is parallel to the H direction, in other words, an I shape.

A reflecting wall capable of reflecting sound waves is provided at the third terminal end 13c. As shown in FIGS. 1 and 2, the reflecting walls provided at the first terminal end 11c, the second terminal end 12c, and the third terminal end 13c are one plate member having a surface perpendicular to the H direction. Such a configuration facilitates manufacturing of the sound absorbing unit 10. However, the reflecting walls provided at each terminal end may be configured as different components.

The sound absorbing unit 10 includes a first waveguide 11, a second waveguide 12 and a third waveguide 13 having different lengths. Therefore, by using the sound absorbing unit 10, it is possible to obtain a sound absorbing effect in a wider frequency band than when using a single waveguide. The sound absorption characteristics of the sound absorbing unit in this embodiment are represented by, for example, the sound absorption coefficient or acoustic impedance for each frequency.

### (1-1) Configuration of Perforated Plate

A perforated plate is a flat member having a plurality of holes. The perforated plate can include, for example, at least one of porous resins, porous metals, porous polymers, and nonwovens. In this embodiment, the surface of the perforated plate is assumed to be substantially flat, but it is not limited to this, and the surface of the perforated plate may be curved, for example.

The sound absorption characteristics of each waveguide are determined by the shape of the waveguide and the parameters of the perforated plate provided with the waveguide (hereinafter referred to as “hole parameters”). Hole parameters include, for example, at least one of the following:
area of perforated plate (area of surface on which holes are formed);
thickness of perforated plate (dimension perpendicular to the surface);
diameter of hole;
the ratio of the area of the holes to the surface of the perforated plate (hereinafter referred to as “hole occupancy”); and
hole shape

The acoustic impedance can be adjusted via the hole parameters of the perforated plate. In addition, the perforated plate also has the effect of lowering the Q value due to thermoviscous resistance.

By giving different sound absorbing characteristics to the plurality of waveguides of the sound absorbing unit 10, the sound absorbing unit 10 as a whole can absorb sound waves in a wide band. The frequency bands of sound waves absorbed by the waveguides may be set so as not to overlap with each other, or may be set so as to partially overlap. Moreover, when it is desired to strengthen the sound absorbing effect of sound waves of a specific frequency, a plurality of waveguides may have the same sound absorbing characteristics.

In a first example of perforated plate configuration, the parameters of each perforated plate (e.g., hole occupancy) are designed individually for each waveguide. That is, the hole parameters of the first perforated plate 11a are optimized according to the sound absorption properties required for the first waveguide 11. The hole parameters of the second perforated plate 12a are optimized according to the sound absorption properties required for the second waveguide 12. The hole parameters of the third perforated plate 13a are optimized according to the sound absorption properties required for the third waveguide 13. Consequently, the hole parameters of the first perforated plate 11a, the hole parameters of the second perforated plate 12a and the hole parameters of the third perforated plate 13a can differ from each other.

According to a first example of perforated plate configuration, the perforated plate provided at the starting end of each waveguide has its hole parameters optimized according to the sound absorption properties required for that waveguide. Therefore, the sound absorbing unit 10 can achieve a high sound absorption coefficient over a wide band.

In a second example of perforated plate configuration, the parameters of each perforated plate are designed to be common between waveguides. That is, the hole parameters of the first perforated plate 11a are identical to the hole parameters of the second perforated plate 12a and the hole parameters of the third perforated plate 13a.

According to the second example of the structure of the perforated plate, the specification of each perforated plate can be standardized, so further improvement in manufacturability can be expected.

### (2) Outline of Embodiment

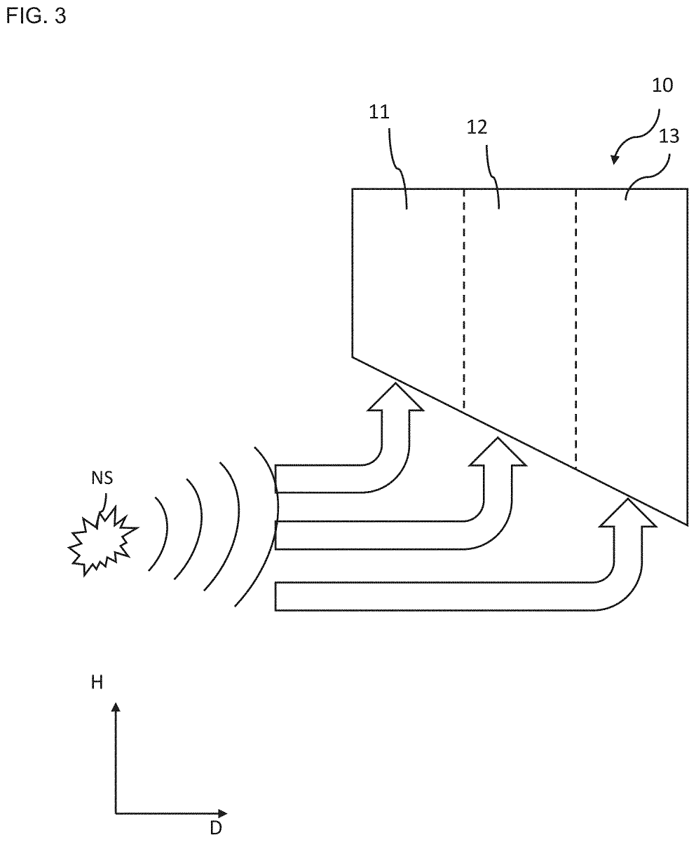

An overview of the present embodiment will be described. FIG. 3 is an explanatory diagram of the outline of the sound absorbing unit of this embodiment.

As shown in FIG. 3, the sound absorbing unit 10 of the present embodiment is installed so that the traveling direction of sound waves from a target noise source NS (an example of a “target noise source”) coincides with the D direction. Each waveguide included in the sound absorbing unit 10 absorbs the frequency component of the sound wave from the noise source NS, which depends on the shape (e.g., length) of the waveguide and hole parameters of the perforated plate. As a result, the sound waves from the noise source NS are greatly attenuated on the D direction side of the sound absorbing unit 10.

As described above, the side wall of each waveguide is rectangular with the longitudinal direction of the HD section of the side wall parallel to the H direction. Therefore, each waveguide has a smaller thickness (dimension in the D direction) than its length (dimension in the H direction). By stacking such waveguides along the D direction, the thickness of the sound absorbing unit 10 (that is, the dimension in the D direction) can also be kept small.

In the sound absorbing unit 10, the ends of all waveguides are included in one plane (terminating surface) perpendicular to the extending direction of the side wall of each waveguide (that is, the H direction). In short, the first terminal end 11c, the second terminal end 12c, and the third terminal end 13c are arranged so as to line up on the terminal plane perpendicular to the H direction. On the other hand, in the sound absorbing unit 10, the surface of the perforated plate of each waveguide is included in one plane (starting surface) that is not orthogonal to the direction in which the side wall of each waveguide extends (that is, the H direction). is provided as follows. In short, the first perforated plate 11a, the second perforated plate 12a, and the third perforated plate 13a are arranged side by side on the starting surface, and the starting surface is not perpendicular to the H direction. In other words, each waveguide has a different distance from the perforated plate to the end because the starting surface is not parallel to the terminating surface. In this manner, the lengths of the waveguides can be made different in order to widen the band of the sound absorption characteristics while the waveguides are arranged in a straight structure.

In the sound absorbing unit 10, the surfaces of the first perforated plate 11a, the second perforated plate 12a, and the third perforated plate 13a are all included in one plane (the starting surface), so the first perforated plate 11a, the second perforated plate 12a and the third perforated plate 13a can be configured as one perforated plate member. That is, three different portions of one perforated plate member can be used as any one of the first perforated plate 11a, the second perforated plate 12a, and the third perforated plate 13a. By sharing one perforated plate member among a plurality of perforated plates in this way, the manufacturability of the sound absorbing unit 10 can be further improved.

### (3) Manufacturing Method of Sound Absorbing Unit

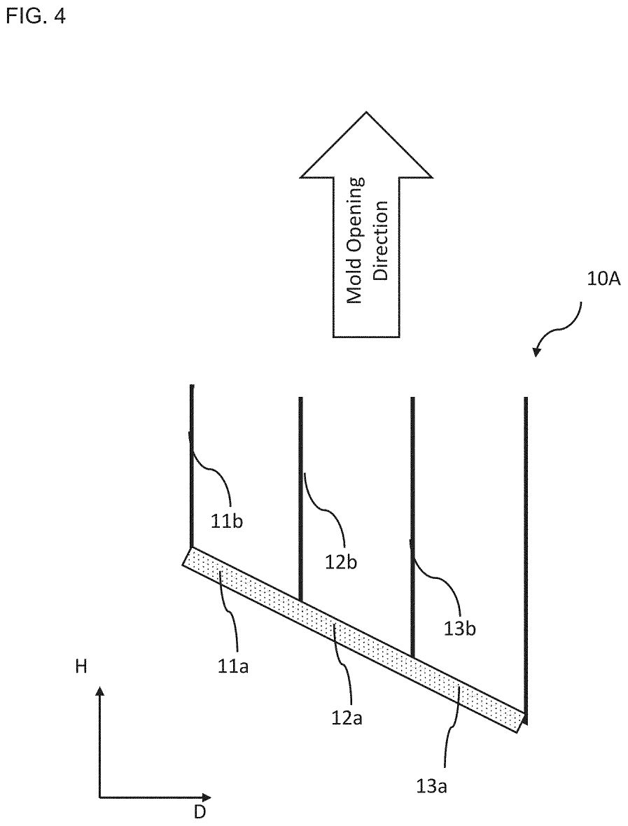

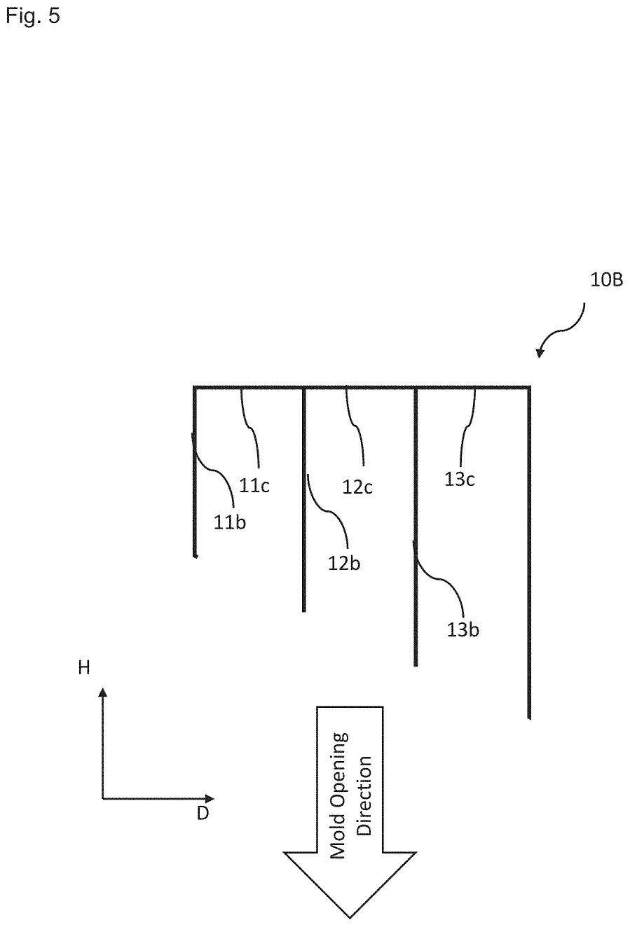

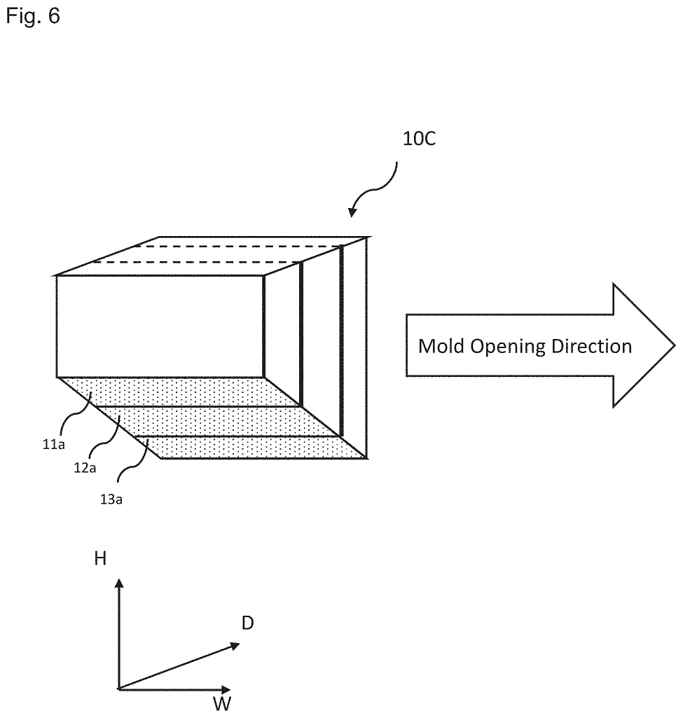

A method of manufacturing the sound absorbing unit will be described. FIG. 4 is a diagram showing an example of a manufacturing outline of the sound absorbing unit of this embodiment. FIG. 5 is a diagram showing an example of a manufacturing outline of the sound absorbing unit of this embodiment. FIG. 6 is a diagram showing an example of a manufacturing outline of the sound absorbing unit of this embodiment.

As described above, in the sound absorbing unit 10, the HD cross section of the side wall of each waveguide is aligned in an I shape. Such a structure is well suited for mass production, for example by injection molding, as explained below.

As shown in FIG. 4, by injection molding with the terminal end of each waveguide in the open state and with the H direction as the mold opening or mold sliding direction, a unit part 10A, which constitutes part of the sound absorbing unit 10, can be integrally molded. The sound absorbing unit 10 can be manufactured by closing the terminal end (that is, the opening) of each waveguide included in the unit part 10A with, for example, a separately manufactured plate member or other means.

As shown in FIG. 5, by injection molding with the starting end of each waveguide in the open state and the opposite direction of the H direction as the mold opening direction or the mold sliding direction, a unit part 10B, which constitutes part of the sound absorbing unit 10, can be integrally molded. The sound absorbing unit 10 can be manufactured by providing, for example, a separately manufactured perforated plate at the starting end (that is, opening) of each waveguide included in the unit part 10B.

As shown in FIG. 6, by injection molding with the end of the side wall of each waveguide in the W direction as an opening and the W direction as the mold opening direction or mold sliding direction, a unit part 10C, which constitutes a part of sound absorbing unit 10, can be integrally molded. The sound absorbing unit 10 can be manufactured by covering the end (that is, the opening) on the W direction side of the side wall of each waveguide included in the unit part 10C with a separately manufactured plate member, for example.

### (4) Application Example of Sound Absorbing Unit

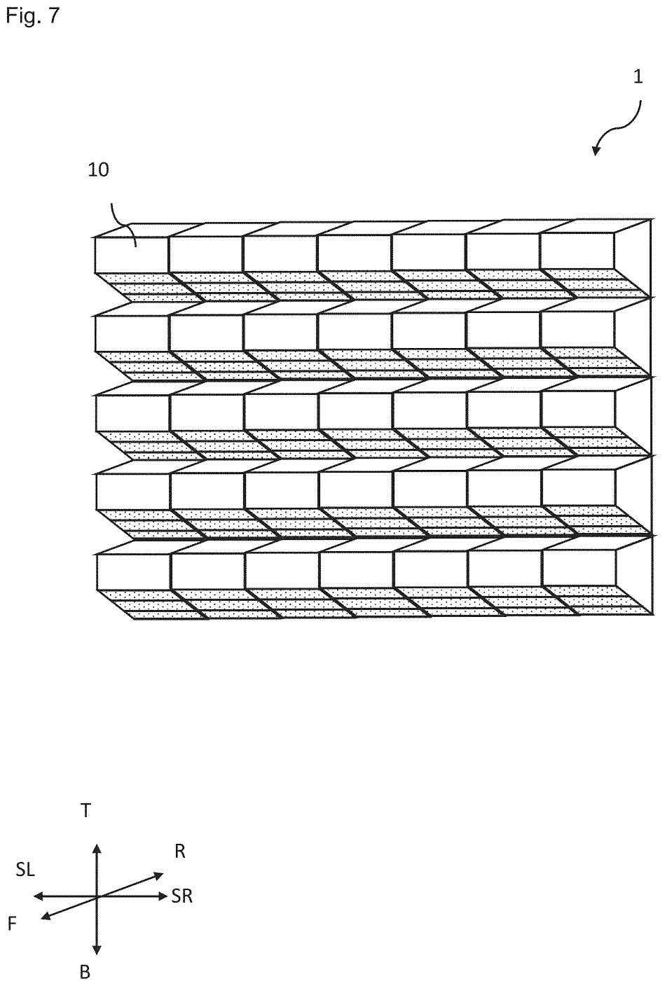

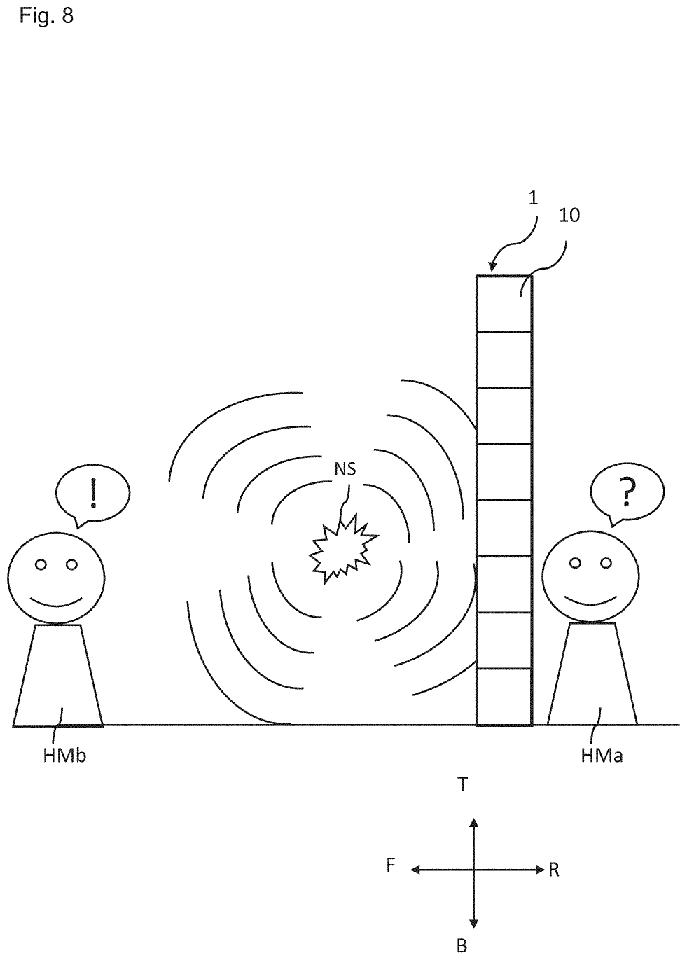

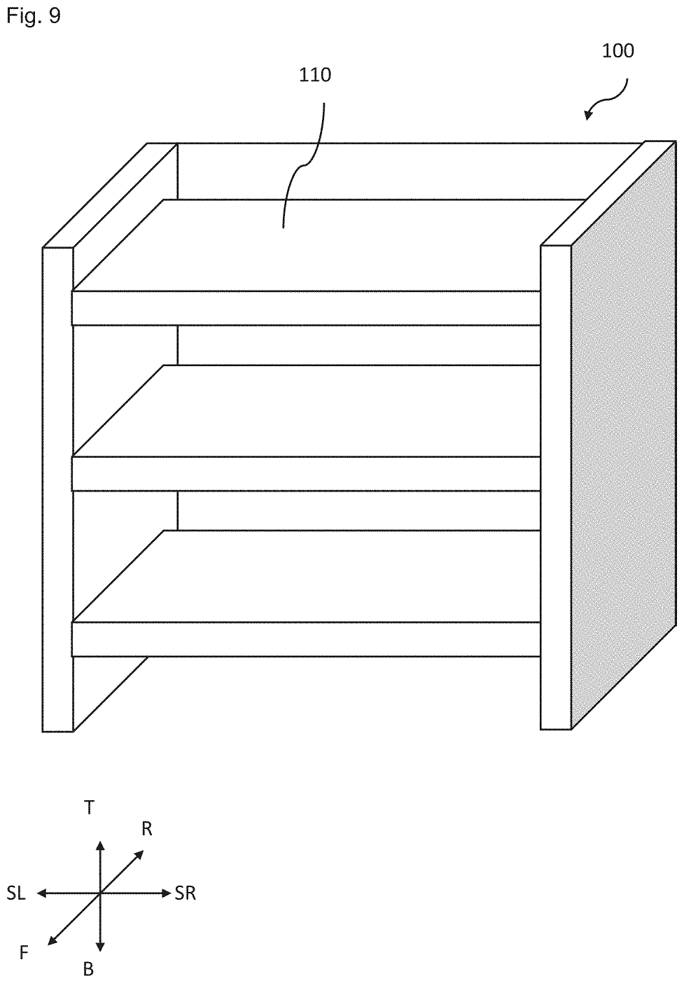

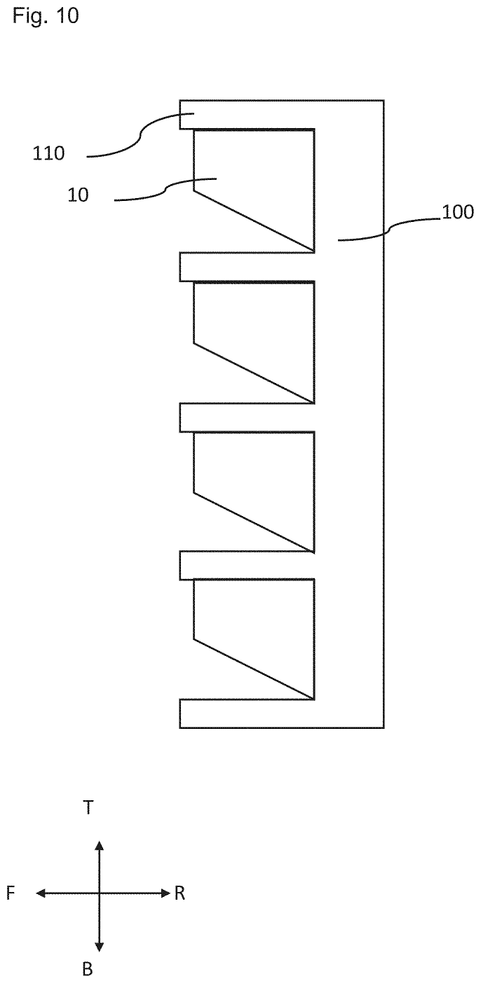

An application example of the sound absorbing unit will be described. FIG. 7 is a diagram showing a sound absorbing structure using the sound absorbing unit of this embodiment. FIG. 8 is an explanatory diagram of an overview of a sound absorbing structure using the sound absorbing unit of this embodiment. FIG. 9 is a perspective view of a support unit that supports the sound absorbing unit of this embodiment. FIG. 10 is an explanatory diagram of the support of the sound absorbing unit by the support unit of this embodiment.

By combining a plurality of sound absorbing units 10, it is possible to construct a sound absorbing structure having a desired outer shape. Although the following description will focus on the case where the sound absorbing structure has a planar wall shape, the outer shape of the sound absorbing structure is not limited to this, and may be, for example, a dome shape or a box shape. Acoustic structures can be used, for example, in acoustic panels, acoustic walls, room walls, ceilings, and floors. In the following description, the vertical axis is defined as the TB axis. Two axes forming an orthogonal coordinate system together with the vertical axis (T-B axis) are defined as the F-R axis and the SL-SR axis, respectively. In this orthogonal coordinate system, upward (T direction), downward (B direction), forward (F direction), backward (R direction), leftward (SL direction), and rightward (SR direction) are defined.

As shown in FIG. 7, a wall-like sound absorbing structure 1 can be constructed by stacking a plurality of sound absorbing units 10 along the vertical direction (T-B direction) and the horizontal direction (SL-SR direction). In the example of FIG. 7, each sound absorbing unit 10 is arranged such that its D direction and H direction are aligned with the backward (R direction) and upward (T direction) of the sound absorbing structure 1, respectively. That is, the sound absorbing structure 1 can absorb sound waves traveling from the forward (F direction) to the backward (R direction).

As shown in FIG. 8, by installing the sound absorbing structure 1 so that the forward (F direction) of the sound absorbing structure 1 faces the target noise source NS, each sound absorbing unit 10 included in the sound absorbing structure 1 can absorb the noise generated by the noise source NS. Therefore, the sound pressure (loudness) of the sound waves emitted from the noise source NS is greatly reduced when passing through the sound absorbing structure 1, and the human HMa located behind the sound absorbing structure 1 (in the direction of R), without being conscious of the presence of noise. In addition, since the sound absorbing structure 1 has a sound absorbing effect, the magnitude of the reflected sound is smaller than that of a wall made of conventional members (for example, a concrete wall). The sound pressure (loudness) of sound waves emitted from the noise source NS is greatly reduced when reflected by the sound-absorbing structure 1, and the noise due to reflected sound felt by the human HMb in front (F direction) of the sound-absorbing structure 1 can be reduced. In addition, when the sound absorbing structure 1 is installed, compared to the case where a wall made of a conventional member is installed at the same position, the volume of sound that wraps behind the wall due to diffraction is also reduced. Due to this effect, the noise felt by the human HMa behind the wall (in the direction of R) can be reduced.

The sound absorbing structure 1 may further include a support unit that supports each sound absorbing unit 10. As shown in FIG. 9, the support unit 100 includes beams 110 extending in the left-right direction (SL-SR direction). By fixing each sound absorbing unit 10 to the beam 110, the support unit 100 supports each sound absorbing unit 10 so as to assume a predetermined posture.

Specifically, the support unit 100 supports the sound absorbing units 10 so that the H direction (i.e., the direction of extension of each waveguide) of each sound absorbing unit 10 is not parallel to the direction of sound wave travel from the noise source NS (i.e., the backward (R) direction of the sound absorption structure 1). Preferably, the support unit 100 supports the sound absorbing units 10 so that the H direction of each sound absorbing unit 10 is orthogonal to the traveling direction of sound waves from the noise source NS. As a result, the thickness of the sound absorbing structure 1 (the dimension in the frontward-backward direction (F-R direction)) does not increase with the dimension of the sound absorbing unit 10 in the H direction.

For example, as shown in FIG. 10, the support unit 100 may support the sound absorbing units 10 so that the H direction of each sound absorbing unit 10 is the upward direction (T direction). Setting the H direction of each sound absorbing unit 10 upward (T direction) also has the effect of preventing the deterioration of the sound absorbing characteristics due to foreign matter blocking the holes of the perforated plate. That is, maintenance costs required to maintain or recover the performance of the sound absorbing structure 1 can be reduced.

As described above, the sound absorbing unit 10 achieves both sound absorption over a wide band and suppression of thickness. Therefore, according to the sound absorbing unit 10, it is possible to configure a thin sound absorbing structure capable of freely customizing the outer shape and absorbing sound over a wide band.

### (5) Summary

As described above, the sound absorbing unit of this embodiment has a plurality of waveguides stacked along the first direction (D direction), and each waveguide has a straight structure extending in the second direction (H direction), which is orthogonal to the first direction. A perforated plate having a plurality of holes is provided at the starting end of each waveguide. Each waveguide is arranged such that the entire perforated plate surface is contained in one plane that is non-orthogonal to the second direction. That is, in this sound absorbing unit, each waveguide has a straight structure with the second direction as the longitudinal direction, but is configured to have different lengths. Thereby, the dimension in the first direction can be suppressed without complicating the arrangement of a plurality of waveguides having different lengths. In other words, it is possible to provide a sound absorbing unit that achieves both sound absorption over a wide band and suppression of thickness, and is highly manufacturable.

The perforated plates provided at the starting end of each waveguide may correspond to different portions of a single perforated plate member. By having a plurality of perforated plates share one perforated plate member in this manner, the manufacturability of the sound absorbing unit can be improved.

Each waveguide may be integrally molded with its starting end or terminal end open. As a result, the unit parts constituting part of the sound absorbing unit can be easily manufactured using injection molding.

A sound absorbing structure may be configured by combining a plurality of sound absorbing units of the present embodiment. As a result, it is possible to configure a thin sound absorbing structure that can freely customize the outer shape and that is capable of absorbing sound over a wide band.

The sound absorbing structure may include a support unit that supports the sound absorbing unit such that the second direction (H direction) of the sound absorbing unit is not parallel (for example, orthogonal) to the traveling direction of sound waves from the target noise source. As a result, the sound absorbing structure can be made thin regardless of the dimension of the sound absorbing unit in the second direction.

In the sound absorbing structure, each sound absorbing unit may be oriented so that the starting end of the waveguide (the end where the perforated plate is provided) is lower than the terminal end (the other end). For example, the sound absorbing structure may include a support unit that supports the sound absorbing unit so that the second direction (H direction) of the sound absorbing unit faces vertically upward. As a result, it is possible to prevent the deterioration of the sound absorption characteristics due to foreign matter (for example, raindrops and dust falling from a position higher than the sound absorbing unit) blocking the holes of the perforated plate. In other words, the maintenance costs required to maintain or restore the performance of the sound absorbing structure can be reduced. Between the plurality of sound absorbing units arranged side by side, there may be gaps that allow ventilation in the R direction (that is, the D direction). With such a configuration, the sound absorbing structure can have the property of allowing air traveling in the R direction to pass while absorbing sound traveling in the R direction. On the other hand, the sound absorbing structure may be configured so that there are no gaps between the plurality of sound absorbing units arranged side by side. With such a configuration, the sound absorbing performance of the sound absorbing structure can be further improved.

### (6) Modification

Modifications of the present embodiment are described.

### (6-1) Modification 1

Modification 1 is described. Modification 1 is an example in which the perforated plates of the waveguides are arranged stepwise.

(6-1-1) Configuration of Sound Absorbing Unit

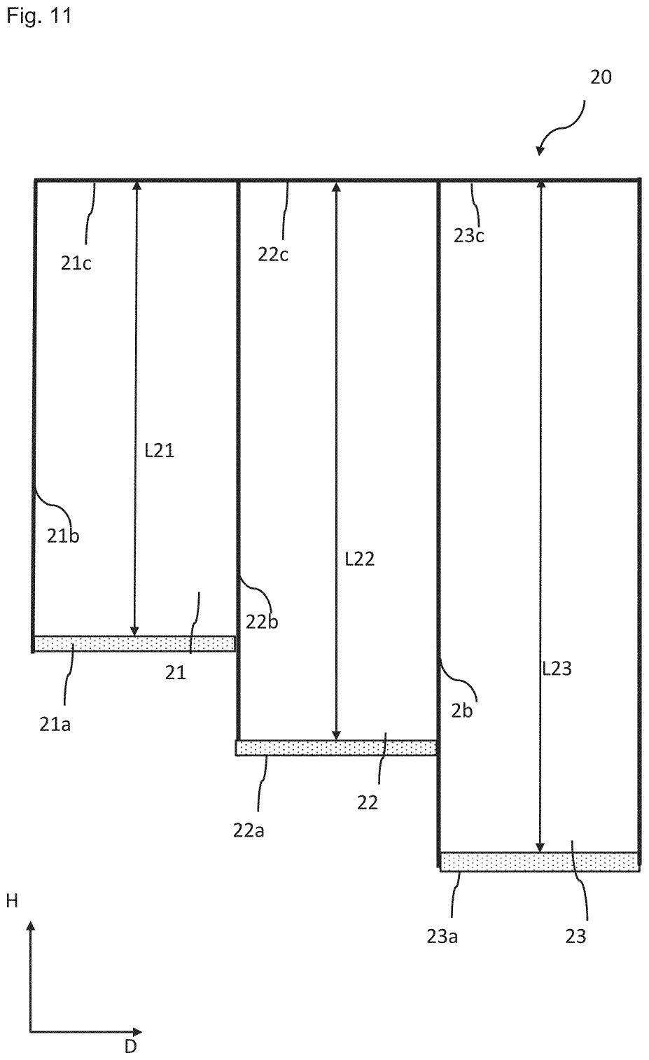

The configuration of the sound absorbing unit will be described. FIG. 11 is an HD cross-sectional view showing a sound absorbing unit of Modification 1.

As shown in FIG. 11, the sound absorbing unit 20 includes a first waveguide 21, a second waveguide 22, and a third waveguide 23. The first to third waveguides 21 to 23 are laminated along the thickness direction (D direction).

The first waveguide 21 has a first starting end, a first side wall 21b and a first terminal end 21c. The length of the first waveguide 21 is represented by L21.

A first perforated plate 21a having a plurality of holes (an example of a “first hole”) through which sound waves can enter is provided at the first starting end. The first perforated plate 21a corresponds to an acoustic impedance matching member.

A first side wall 21b connects the first starting end and the first terminal end 21c. In the example of FIG. 11, the HD section of the outline of the first side wall 21b is a rectangle whose longitudinal direction is parallel to the H direction, in other words, an I shape.

The first terminal end 21c is provided with a reflecting wall capable of reflecting sound waves.

As shown in FIG. 11, the second waveguide 22 has a second starting end, a second side wall 22b and a second terminal end 22c. The second waveguide 22 is laminated along the D direction with respect to the first waveguide 21. Specifically, the second waveguide 22 is arranged such that a second starting end in contact with the first starting end, a second side wall 22b in contact with the first side wall 21b, and a second terminal end 22c in contact with the first terminal end 21c.

The length of the second waveguide 22 is represented by L22. The length of the second waveguide 22 is longer than the length of the first waveguide 21. That is, the second waveguide 22 can absorb sound waves in a frequency band different from that of the first waveguide 21.

The second starting end is provided with a second perforated plate 22a having a plurality of holes (an example of “second holes”) through which sound waves can enter. The second perforated plate 22a corresponds to an acoustic impedance matching member.

A second side wall 22b connects the second starting end and the second terminal end 22c. In the example of FIG. 11, the HD cross section of the contour of the second side wall 22b is a rectangle whose longitudinal direction is parallel to the H direction, in other words, an I shape.

The second terminal end 22c is provided with a reflecting wall capable of reflecting sound waves.

As shown in FIG. 11, the third waveguide 23 has a third starting end, a third side wall 23b and a third terminal end 23c. The third waveguide 23 is laminated along the D direction with respect to the second waveguide 22. Specifically, the third waveguide 23 is arranged such that the third starting end in contact with the second starting end, the third side wall 23b in contact with the second side wall 22b, and the third terminal end 23c in contact with the second side wall 22b.

The length of the third waveguide 23 is represented by L23. The length of the third waveguide 23 is longer than the length of the second waveguide 22. That is, the third waveguide 23 can absorb sound waves of frequencies different from those of the second waveguide 22.

A third perforated plate 23a having a plurality of holes (an example of a “third hole”) through which sound waves can enter is provided at the third starting end. The third perforated plate 23a corresponds to an acoustic impedance matching member.

A third side wall 23b connects the third starting end and the third terminal end 23c. In the example of FIG. 11, the HD section of the contour of the third side wall 23b is a rectangle whose longitudinal direction is parallel to the H direction, in other words, an I shape.

A reflecting wall capable of reflecting sound waves is provided at the third terminal end 23c.

The sound absorbing unit 20 includes a first waveguide 21, a second waveguide 22 and a third waveguide 23 having different lengths. Therefore, by using the sound absorbing unit 20, it is possible to obtain a sound absorbing effect in a wider frequency band than when using a single waveguide.

(6-1-1-1) Configuration of Perforated Plate

A perforated plate is a flat member having a plurality of holes. The perforated plate can include, for example, at least one of porous resins, porous metals, porous polymers, and nonwovens.

In a first example of perforated plate configuration, the parameters of each perforated plate (e.g., hole occupancy) are designed individually for each waveguide. That is, the hole parameters of the first perforated plate 21a are optimized according to the sound absorption properties required for the first waveguide 21. The hole parameters of the second perforated plate 22a are optimized according to the sound absorption properties required for the second waveguide 22. The hole parameters of the third perforated plate 23a are optimized according to the sound absorption properties required for the third waveguide 23. Consequently, the hole parameters of the first perforated plate 21a, the hole parameters of the second perforated plate 22a and the hole parameters of the third perforated plate 23a can differ from each other.

According to a first example of perforated plate configuration, the perforated plate provided at the starting end of each waveguide has its hole parameters optimized according to the sound absorption properties required for that waveguide. Therefore, the sound absorbing unit 20 can achieve a high sound absorption coefficient over a wide band.

In a second example of perforated plate configuration, the parameters of each perforated plate are designed to be common between waveguides. That is, the hole parameters of the first perforated plate 21a are identical to the hole parameters of the second perforated plate 22a and the hole parameters of the third perforated plate 23a.

According to the second example of the structure of the perforated plate, the specification of each perforated plate can be standardized, so further improvement in manufacturability can be expected.

(6-1-2) Outline of Modification

An outline of Modification 1 will be described.

As described above, the side wall of each waveguide is rectangular with the longitudinal direction of the HD section of the side wall parallel to the H direction. Therefore, each waveguide has a smaller thickness (dimension in the D direction) than its length (dimension in the H direction). By stacking such waveguides along the D direction, the thickness of the sound absorbing unit 20 (that is, the dimension in the D direction) can also be kept small.

In the sound absorbing unit 20, the terminal ends of all the waveguides are included in one plane (termination plane) orthogonal to the extending direction of the side wall of each waveguide (that is, the H direction). In short, the first terminal end 21c, the second terminal end 22c, and the third end 23c are arranged side by side on the terminal surface, and the terminal surface is perpendicular to the H direction. On the other hand, in the sound absorbing unit 20, the surface of the perforated plate of each waveguide is provided so as to be included in a plane orthogonal to the extending direction of the side wall of each waveguide (that is, the H direction). However, the planes in which the surface of each perforated plate is included are different from each other. In short, in each waveguide, the perforated plate surface and terminal end are parallel to each other, but the distance between them varies from waveguide to waveguide. In this manner, the lengths of the waveguides can be made different in order to widen the band of the sound absorption characteristics while the waveguides are arranged in a straight structure.

In summary, in both the present embodiment and Modification 1, each waveguide is arranged such that the surface of each perforated plate is not simultaneously included in any plane perpendicular to the H direction, so that each waveguide are arranged in a straight structure, and the length of each waveguide is made different in order to widen the band of sound ab sorption characteristics.

(6-1-3) Summary

As described above, the sound absorbing unit of Modification 1 includes a plurality of waveguides stacked along the first direction (D direction), and each waveguide having a straight structure extending in the second direction (H direction) orthogonal to the first direction. A perforated plate having a plurality of holes is provided at the starting end of each waveguide. Each waveguide is arranged such that the surface of each perforated plate is contained in a plane orthogonal to the second direction but different from each other. That is, in this sound absorbing unit, each waveguide has a straight structure with the second direction as the longitudinal direction, but is configured to have different lengths. Thereby, the dimension in the first direction can be suppressed without complicating the arrangement of a plurality of waveguides having different lengths. In other words, it is possible to provide a sound absorbing unit that achieves both sound absorption over a wide band and suppression of thickness, and is highly manufacturable.

(6-2) Modification 2

Modification 2 is described. Modification 2 is an example in which at least one waveguide included in the sound absorbing unit is bent.

(6-2-1) Configuration of Sound Absorbing Unit

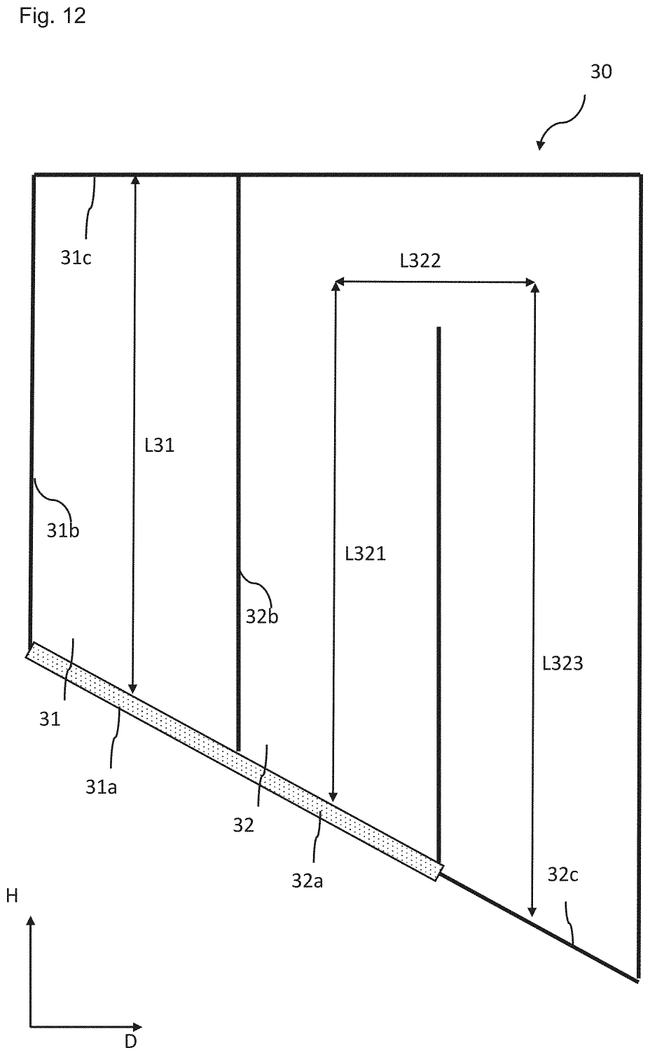

The configuration of the sound absorbing unit will be described. FIG. 12 is an HD cross-sectional view showing a sound absorbing unit of Modification 2.

As shown in FIG. 12, the sound absorbing unit 30 includes a first waveguide 31 and a second waveguide 32. The first waveguide 31 to the second waveguide 32 are laminated along the thickness direction (D direction).

As shown in FIG. 12, the first waveguide 31 has a first starting end, a first side wall 31b and a first terminal end 31c. The length of the first waveguide 31 is represented by L31.

A first perforated plate 31a having a plurality of holes (an example of a “first hole”) through which sound waves can enter is provided at the first starting end. The first perforated plate 31a corresponds to an acoustic impedance matching member.

A first side wall 31b connects the first starting end and the first terminal end 31c. In the example of FIG. 12, the HD section of the contour of the first side wall 31b is a rectangle whose longitudinal direction is parallel to the H direction, in other words, an I shape.

The first terminal end 31c is provided with a reflecting wall capable of reflecting sound waves.

As shown in FIG. 12, the second waveguide 32 comprises a second starting end, a second side wall 32b and a second terminal end 32c. The second waveguide 32 is laminated along the D direction with respect to the first waveguide 31. Specifically, the second waveguide 32 is arranged such that the second starting end is in contact with the first starting end, the second sidewall 32b is in contact with the first terminal end 31c and the first sidewall 31b, and the second terminal end 32c is in contact with the second starting end.

The length of the second waveguide 32 is represented by L321+L322+L333. The length of the second waveguide 32 is longer than the length of the first waveguide 31. That is, the second waveguide 32 absorbs sound waves with frequencies lower than those of the first waveguide 31.

A second perforated plate 32a having a plurality of holes (an example of a “second hole”) through which sound waves can enter is provided at the second starting end. The second perforated plate 32a corresponds to an acoustic impedance matching member.

A second side wall 32b connects the second starting end and the second terminal end 32c. In the example of FIG. 12, the HD cross section of the contour of the second side wall 32b is a rectangle bent twice at 90 degrees, in other words, a U shape. In short, the second sidewall 32b has a first portion extending along the H direction and a second portion extending along a direction (e.g., D direction) non-parallel (e.g., orthogonal) to the H direction. and a third portion extending along a direction opposite to the H direction.

The second terminal end 32c is provided with a reflecting wall capable of reflecting sound waves.

The sound absorbing unit 30 includes a first waveguide 31 and a second waveguide 32 having different lengths. Therefore, by using the sound absorbing unit 30, it is possible to obtain a sound absorbing effect in a wider frequency band than when using a single waveguide.

(6-2-1-1) Configuration of Perforated Plate

A perforated plate is a flat member having a plurality of holes. The perforated plate can include, for example, at least one of porous resins, porous metals, porous polymers, and nonwovens.

In a first example of perforated plate configuration, the parameters of each perforated plate (e.g., hole occupancy) are designed individually for each waveguide. That is, the hole parameters of the first perforated plate 31a are optimized according to the sound absorption properties required for the first waveguide 31. The hole parameters of the second perforated plate 32a are optimized according to the sound absorption properties required for the second waveguide 32. Consequently, the hole parameters of the first perforated plate 31a and the hole parameters of the second perforated plate 32a can differ from each other.

According to a first example of perforated plate configuration, the perforated plate provided at the starting end of each waveguide has its hole parameters optimized according to the sound absorption properties required for that waveguide. Therefore, the sound absorbing unit 30 can achieve a high sound absorption coefficient over a wide band.

In a second example of perforated plate configuration, the parameters of each perforated plate are designed to be common between waveguides. That is, the hole parameters of the first perforated plate 31a and the hole parameters of the second perforated plate 32a are identical.

According to the second example of the structure of the perforated plate, the specification of each perforated plate can be standardized, so further improvement in manufacturability can be expected.

(6-2-2) Outline of Modification

An outline of Modification 2 will be described.

As mentioned above, the second waveguide 32 is longer than the first waveguide 31. However, the dimension of the second waveguide 32 in the H direction is smaller than the length of the second waveguide 32 because the second side wall 32b includes portions extending in directions other than the H direction. In this way, by allowing a limited increase in the dimension in the D direction due to bending of the waveguide, a waveguide with a low resonance frequency can be obtained while preventing an extreme increase in the dimension in the H direction of the sound absorbing unit. That is, it is possible to improve the sound absorption characteristics in the low frequency band. By arranging the bent waveguides so as not to straddle other waveguides, it is possible to maintain the manufacturability of the sound absorbing unit (for example, it is possible to manufacture unit parts by injection molding).

(6-2-3) Summary

As described above, the sound absorbing unit has a plurality of waveguides stacked along the first direction (D direction), with at least one waveguide having a bending structure that extends in a direction different from the second direction (e.g., the opposite direction of the second direction) in addition to a portion that extends in the second direction (H direction), which is orthogonal to the first direction. As a result, it is possible to enhance the sound absorption characteristics in the low frequency band while suppressing an extreme increase in the dimension of the sound absorbing unit in the second direction due to the adoption of a long waveguide.

### (6-3) Modification 3

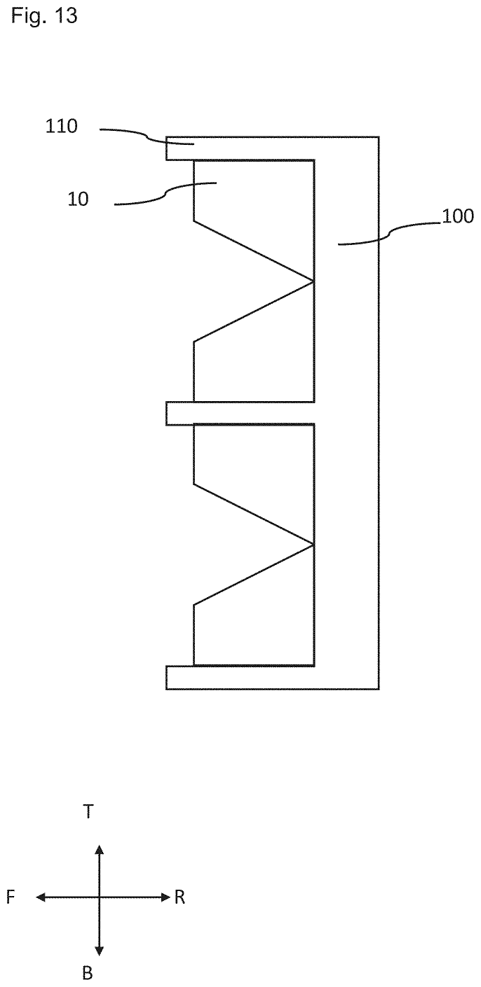

Modification 3 is described. Modification 3 is an example in which a sound absorbing structure is configured by combining adjacent sound absorbing units among a plurality of sound absorbing units so as to have plane-symmetrical postures. FIG. 13 is an explanatory diagram of support of the sound absorbing unit by the support unit of Modification 3.

As described above, by combining a plurality of sound absorbing units 10, it is possible to construct a sound absorbing structure having a desired outer shape. Specifically, by stacking a plurality of sound absorbing units 10 along the vertical direction (T-R direction) and the horizontal direction (SL-SR direction), a wall-like sound absorbing structure can be constructed.

In Modification 3, the sound absorbing unit 10 may be arranged so that its D direction and H direction are respectively aligned with the backward (R direction) and upward (T direction) of the sound absorbing structure (taking the first posture). In some cases, the D direction and the H direction are aligned with the backward (R direction) and the downward (B direction) of the sound absorbing structure, respectively (taking the second posture).

As an example, as shown in FIG. 13, the support unit 100 may support one sound-absorbing unit 10 by securing it to the beam 110 so that it is in a first posture, and may support another sound-absorbing unit 10 adjacent to that sound-absorbing unit 10 in the vertical direction (T-B direction) by securing it to the beam 110 so that it is in a second posture. In this manner, the adjacent sound absorbing units 10 take plane-symmetrical postures, so that the symmetry of the sound absorbing characteristics of the sound absorbing structure can be enhanced.

### (6-4) Modification 4

Modification 4 is described. Modification 4 is a design example of the sound absorbing unit.

(6-4-1) Configuration of Design Apparatus

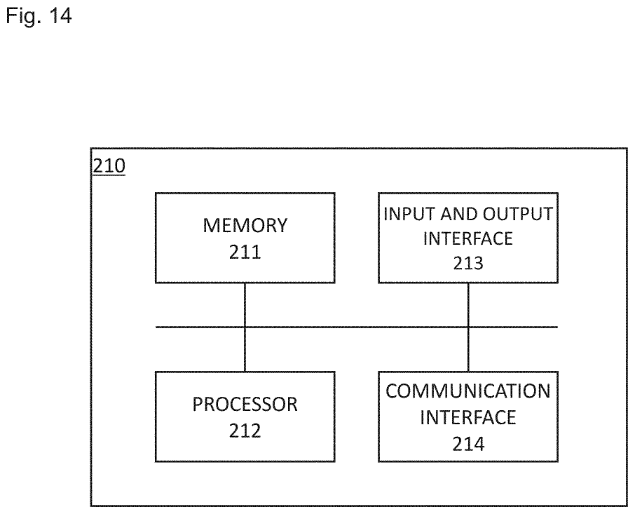

A configuration of a design apparatus that executes the design processing of Modification 4 will be described. FIG. 14 is a diagram illustrating an example of a design apparatus that executes design processing according to Modification 4.

As shown in FIG. 14, the design apparatus 210 includes a storage device 211, a processor 212, an input/output interface 213, and a communication interface 214.

The memory 211 is configured to store a program and data. The memory 211 is, for example, a combination of a ROM (read only memory), a RAM (random access memory), and a storage (for example, a flash memory or a hard disk).

Programs include, for example, the following programs:
OS (Operating System) program; and
Programs of applications that execute information processing (e.g. web browsers).

The data includes, for example, the following data:
Data referenced in an information processing; and
Data obtained by executing an information processing (that is, an execution result of an information processing).

The processor 212 is configured to implement the functions of the design apparatus 210 by activating programs stored in the storage device 211 and processing data. Processor 212 is an example of a computer. The programs and data stored by the storage device 211 may be provided via a network, or may be provided by being recorded on a computer-readable recording medium.

The input/output interface 213 is configured to acquire user's instruction from an input device connected to the design apparatus 210 and output information to an output device connected to the design apparatus 210.

The input device is, for example, a keyboard, a pointing device, a touch panel, or a combination thereof.

The output device is, for example, a display.

Communication interface 214 is configured to control communications between design apparatus 210 and an external device (e.g., a server).

(6-4-2) Design Processing

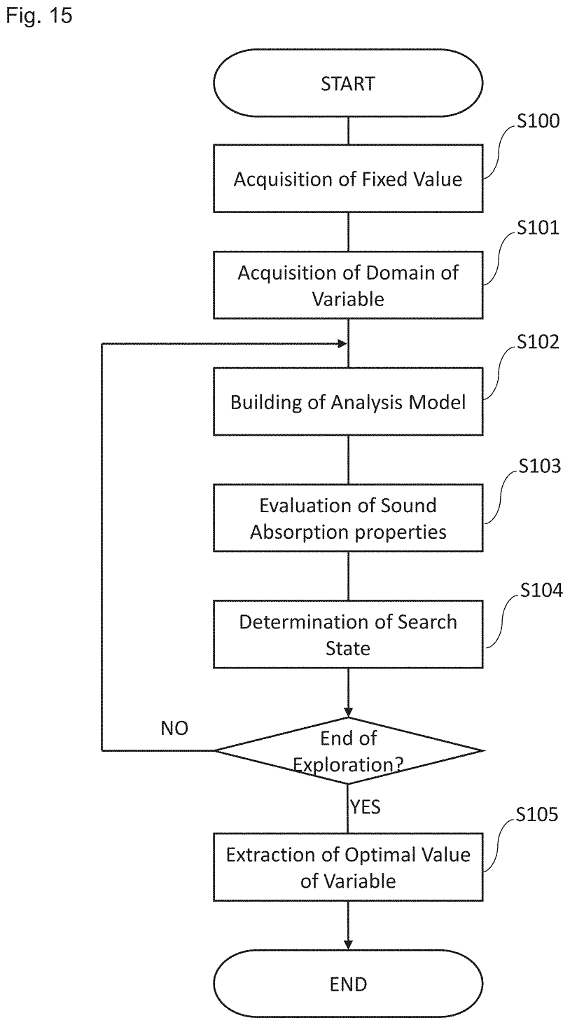

The design processing of modification 4 will be described. FIG. 15 is a diagram showing the overall flow of design processing of Modification 4.

The flow of FIG. 15 is started, for example, in response to an operation by a designer (an example of a user).

As shown in FIG. 15, the design apparatus 210 executes acquisition of fixed value (S100). Specifically, the processor 212 acquires fixed values that are set for the design parameters of the sound absorbing unit 10. As an example, the processor 212 acquires the fixed values according to the designer's input or by reading a file in which the fixed values are stored.

Here, the design parameters of the sound absorbing unit 10 include at least one of the following.
Number of waveguides;
Hole parameters of the perforated plate provided in each waveguide (for example, hole diameter and number of holes);
Length of each waveguide (for example, the length of the longest waveguide (L13 in the example of FIG. 2) and the length of the shortest waveguide (L11 in the example of FIG. 2));
Thickness of the sound absorbing unit 10 (that is, dimension in the D direction)
Thickness of the sidewall of each waveguide (i.e., dimension in the D direction)

In the following description, in step S100, the processor 212 is assumed to acquire fixed values set for the number of waveguides, the length of the longest waveguide, the thickness of the sound absorbing unit 10, and the thickness of the side wall of each waveguide, and treat the hole parameters of the perforated plate that are provided in each waveguide and the length of the shortest waveguide as variables.

After the step S100, the design apparatus 210 executes acquisition of domain of variables (S101).

Specifically, the processor 212 acquires the domain of the design parameters treated as variables (i.e., the perforated plate hole parameters provided in each waveguide and the length of the shortest waveguide). As an example, the processor 212 acquires the domain of the variable according to the designer's input or by reading a file in which the domain of the variable is stored.

After step S101, the design apparatus 210 executes construction of analysis model (S102). Specifically, the processor 212 constructs an analysis model of the sound absorbing unit 10 by setting numerical values for each design parameter. Processor 212 has set fixed values to some of the design parameters in step S100. The processor 212 substitutes numerical values selected from the domain set in step S101 for the design parameters corresponding to the remaining variables.

After step S102, the design apparatus 210 executes evaluation of sound absorption characteristics (S103).

Specifically, the processor 212 obtains an evaluation value of the sound absorption characteristics of the analysis model constructed in step S102 by analyzing the sound absorption characteristics of the analysis model. As an example, the design apparatus 210 analyzes the average sound absorption or reflectance of the analytical model over the design frequencies. In addition, the evaluation method of the sound absorption characteristics is not limited to this. For example, the design apparatus 210 may analyze the average transmittance of the analytical model over the design frequencies.

After step S103, the design apparatus 210 executes search state determination (S104). Specifically, the processor 212 determines whether the domain acquired in step S101 has been searched for each variable (that is, construction and analysis evaluation of the sound absorption of a plurality of analysis models with different design parameters from each other using all the numerical values that can be selected from the domain has been completed).

When it is determined in step S104 that the search has ended, the design apparatus 210 executes extraction of optimum values of the variables (S105).

Specifically, the processor 212 extracts, as the optimal values, the numerical values set for the design parameters (variables) of the analysis model that show the highest evaluation value in the repeated evaluations of sound absorption characteristics (S103). After step S105, the flow of FIG. 15 ends.

If it is not determined in step S104 that the search has ended, the design apparatus 210 constructs an analysis model (S102).

As described above, the design apparatus of Modification 4 treats part of the design values of the sound absorbing unit as variables, and searches for values of variables that optimize the sound absorption characteristics by repeatedly constructing an analysis model by assigning values to each variable, and evaluating the sound absorption characteristics of the constructed analysis model. As a result, it is possible to design (that is, determine design parameters) a sound absorbing unit with optimized sound absorbing characteristics while reducing the number of variables and suppressing the amount of calculation.

### (7) Other Modifications

In the above description, it was assumed that the sound absorbing unit includes two or three waveguides of different lengths. However, the sound absorbing unit may contain four or more waveguides of different lengths.

In the above description, it has been described that a reflecting wall capable of reflecting sound waves is provided at the end of each waveguide of the sound absorbing unit. This reflective wall may be part of the structure of the sound absorbing unit (that is, the terminal end may be configured as a closed end) or may not be part of the structure of the sound absorbing unit. As an example of the latter, the end of each waveguide of the sound absorbing unit may be configured as an opening, and the end of each waveguide may be blocked by another structure when the sound absorbing unit is installed, thereby utilizing the other structure as a reflecting wall. Other structures may be, for example, the walls that make up the installation environment, or the beams 110 of the support unit. As a result, for example, the unit part 10A shown in FIG. 4 can be combined with other structures to function as a sound absorbing unit, so the number of components of the sound absorbing unit can be reduced and manufacturability can be improved.

In the above description, an example in which the sound absorbing structure includes the support unit is shown. However, the sound absorbing unit may be configured so that it can stand on its own in a predetermined posture and can be connected to another sound absorbing unit. In this case, the sound absorbing structure does not have to be provided with a support unit.

In the above description, an example of forming a wall-shaped sound absorbing structure by stacking a plurality of sound absorbing units along the vertical direction (T-R direction) and the horizontal direction (SL-SR direction) has been shown. However, by laminating arbitrary sound absorbing units described in the above description along arbitrary directions, it is possible to form various shapes of sound absorbing structures. As an example, a bar-shaped sound absorbing structure can be configured by stacking a plurality of sound absorbing units along only one of the vertical direction (TR direction) or the horizontal direction (SL-SR direction).

In the above description, an example in which the side wall of the waveguide of the sound absorbing unit is not bent and an example in which the side wall is bent twice are shown. However, the sidewalls may be folded only once or more than three times.

In Modification 2, at least one waveguide of the sound absorbing unit is bent by 90 degrees. However, a waveguide may be configured so that the side wall of the waveguide has a contour shape different from the curved surface formed by straight lines connecting points on the contour of the perforated plate provided at the starting end of the waveguide and points on the contour of the terminal end of the waveguide. That is, the bending angle is not limited to 90 degrees, and the size of the sound absorbing unit in the H direction can be suppressed without bending. For example, a waveguide may include a portion that extends along a curve.

In Modification 3, an example of configuring a sound absorbing structure by combining a plurality of sound absorbing units of the present embodiment has been described. However, a sound absorbing structure may be configured by combining a plurality of sound absorbing units of Modification 1 or Modification 2, or sound absorbing units of different embodiments or Modifications may be combined. Also, at least one of the various sound absorbing units described above may be combined with a member different from the various sound absorbing units described above (for example, a sound absorbing unit having a different shape or a conventional sound insulating member) to form a sound absorbing structure.

A perforated plate provided at the starting of each waveguide may be configured to be movable or detachable. This facilitates fine adjustment of the length of each waveguide. Similarly, the reflective wall provided at the end of each waveguide may be configured to be movable or detachable. This facilitates fine adjustment of the length of each waveguide.

In the above description, an acoustic impedance matching member (perforated plate) is provided at the starting end of each waveguide. Additional matching members may be added from the starting end to the closed end of each waveguide. The matching member may be detachable.

According to the above disclosure, a sound absorbing structure with high manufacturability can be provided.

Although the embodiments of the present invention are described in detail above, the scope of the present invention is not limited to the above embodiments. Further, various modifications and changes can be made to the above embodiments without departing from the spirit of the present invention. In addition, the above embodiments and modifications can be combined.

### (8) Appendix

Matters described in the embodiments will be added below.

(Appendix 1)

A sound absorbing unit (10, 20, 30) comprising:

a first waveguide (11, 21,31) having a first starting end, a first terminal end (11c, 21c, 31c) and

a first sidewall (11b, 21b, 31b) connecting the first starting end and the first terminal end; and

a second waveguide (12, 22, 32) laminated to the first waveguide along a first direction (direction D) and having a second starting end, a second terminal end (12c, 22c, 32c) and a second sidewall (12b, 22b, 32b) connecting the second starting end and the second terminal end, and wherein

a first perforated plate (11a, 21a, 31a) having a plurality of first holes through which sound waves can be incident is provided at the first starting end,

at least part of the first sidewall extends from the first starting end along a second direction (H direction) perpendicular to the first direction,

a second perforated plate (12a, 22a, 32a) having a plurality of second holes through which sound waves can be incident is provided at the second starting end,

at least a portion of the second sidewall extends along the second direction from the second starting end;

length of the second waveguide is different from length of the first waveguide,

the first waveguide and the second waveguide are arranged such that a surface of the first perforated plate and a surface of the second perforated plate are not simultaneously contained in any plane orthogonal to the second direction.

(Appendix 2)

The sound absorbing unit (10) according to appendix 1, wherein

The first waveguide (11) and the second waveguide (11) are arranged such that both the surface of the first perforated plate (11a) and the surface of the second perforated plate (12a) are contained in a plane that is not orthogonal to the second direction.

(Appendix 3)

The sound absorbing unit (10, 30) according to appendix 2, wherein

the first perforated plate (11a, 31a) and the second perforated plate (12a, 32a) correspond to different portions of one perforated plate member.

(Appendix 4)

The sound absorbing unit (20) according to appendix 1, wherein

the first waveguide (21) and the second waveguide (22) are arranged such that the surface of the first perforated plate (21a) is contained in a first plane which is orthogonal to the second direction, and the surface of the second perforated plate (22a) is contained in the in a second plane orthogonal to the second direction and different from the first plane.

(Appendix 5)

The sound absorbing unit (10, 20) according to any one of appendices 1 to 4, wherein

at least one of the first sidewall (11b, 21b) and the second sidewall (12b, 22b) does not include a portion extending in a direction other than the second direction.

(Appendix 6)

The sound absorbing unit (30) according to any one of appendices 1 to 5, wherein

at least one of the first sidewall and the second sidewall (32b) includes a portion extending in a direction other than the second direction.

(Appendix 7)

The sound absorbing unit according to appendix 6, wherein

at least one of the first sidewall and the second sidewall has a portion extending along the second direction and a portion extending along a direction parallel to and opposite to the second direction.

(Appendix 8)

The sound absorbing unit according to any one of appendices 1 to 7, wherein

the first waveguide and the second waveguide are integrally molded with the first terminal end and the second terminal end being open.

(Appendix 9)

The sound absorbing unit according to any one of appendices 1 to 7, wherein

the first waveguide and the second waveguide are integrally molded with the first starting end and the second starting end being open.

(Appendix 10)

A sound absorbing structure (1) comprising a plurality of sound absorbing units including a first sound absorbing unit, and wherein

each of the plurality of sound absorbing units corresponds to the sound absorbing unit according to any one of appendices 1 to 9.

(Appendix 11)

The sound absorbing structure according to appendix 10, further comprising a support unit (100) for supporting the plurality of sound absorbing units, and wherein

the support unit supports the first sound absorbing unit such that the second direction is not parallel to the traveling direction of sound waves from the target noise source.

(Appendix 12)

The sound absorbing structure according to appendix 11, wherein the supporting unit supports the first sound absorbing unit such that the second direction is orthogonal to the traveling direction of sound waves from the target noise source.

(Appendix 13)

The sound absorbing structure according to appendix 10, further comprising a support unit (100) for supporting the plurality of sound absorbing units, and wherein

the support unit supports the first sound absorbing unit so that the second direction is vertically upward.

(Appendix 14)

The sound absorbing structure according to any one of appendices 11 to 13, wherein

the support unit supports the first sound absorbing unit so as to take a first posture, and the second sound absorbing unit adjacent to the first sound absorbing unit takes a second posture that is plane-symmetrical with the first posture.

(Appendix 15)

The sound absorbing structure according to any one of appendices 11 to 14, wherein

the support unit comprises a beam (110) bounded by a first terminal end and a second terminal end.

(Appendix 16)

A computer-implemented design method for a sound absorbing unit according to any one of appendices 1 to 9, the method comprising

building an analysis model of the sound absorbing unit by substituting values for a first variable for the plurality of first holes, a second variable for the plurality of second holes, and a third variable for the length of the first waveguide (S102);

evaluating the sound absorption characteristics of the analysis model (S103); and

searching for values of the first variable, the second variable, and the third variable that optimize the sound absorption characteristics (S102-S105).

### REFERENCE SIGNS LIST

1: Sound absorbing structure
10: Sound absorbing unit
10A: Unit part
10B: Unit part
10C: Unit part
11: First waveguide
11a: First perforated plate
12: Second waveguide
12a: Second perforated plate
13: Third waveguide
13a: Third perforated plate
20: Sound absorbing unit
21: First waveguide
21a:First perforated plate
22: Second waveguide
22a: Second perforated plate
23: Third waveguide
23a: Third perforated plate
30: Sound absorbing unit
31: First waveguide
31a: First perforated plate
32: Second waveguide
32a: Second perforated plate
100: Support unit
110: Beam
210: Design apparatus
211: Storage device
212: Processor
213: Input/output interface
214: Communication interface

What is claimed is:

1. A sound absorbing unit, comprising:
a perforated plate that is a plate member having a plurality of holes;
a first cavity extending in a first direction, the first cavity allowing sound waves to enter through a plurality of holes present in a first region of the perforated plate; and
a second cavity extending substantially parallel to the first direction, the second cavity allowing sound waves to enter through a plurality of holes present in a second region of the perforated plate, wherein
the first cavity and the second cavity are arranged in a second direction perpendicular to the first direction,
a surface of the perforated plate is orthogonal to neither the first direction nor the second direction, and
the first cavity and the second cavity have different lengths in the first direction.

2. The sound absorbing unit according to claim 1, wherein at least one of a number and diameter of holes existing in the first region of the perforated plate is different from a number and diameter of holes existing in the second region of the perforated plate.

3. The sound absorbing unit according to claim 1, wherein the first cavity and the second cavity function as resonators having different sound absorption characteristics.

4. The sound absorbing unit according to claim 1, wherein the surface of the perforated plate is substantially planar.

5. The sound absorbing unit according to claim 1, wherein the surface of the perforated plate is curved.

6. The sound absorbing unit according to claim 1, wherein
the sound absorbing unit is a frustum;
the perforated plate is provided on a surface different from a bottom surface of the frustum, and
an interior of the sound absorbing unit is divided into a plurality of cavities by side walls.

7. The sound absorbing unit according to claim 1, wherein
the first cavity has a portion extending in the first direction and a portion extending non-parallel to the first direction.

8. The sound absorbing unit according to claim 1, further comprising a third cavity extending substantially parallel to the first direction, the third cavity allowing sound waves to enter through a plurality of holes present in a third region of the perforated plate, and wherein
the first cavity, the second cavity, and the third cavity are arranged in the second direction, and
the first cavity, the second cavity, and the third cavity have different lengths in the first direction.

9. The sound absorbing unit according to claim 1, wherein the perforated plate is provided at one end of each of the first cavity and the second cavity in the first direction, and
another plate member is provided at another end in the first direction of each of the first cavity and the second cavity.

10. The sound absorbing unit according to claim 9, wherein the other plate member has a surface substantially perpendicular to the first direction.

11. A method for manufacturing the sound absorbing unit according to claim 1, the method comprising:
integrally molding a part other than the perforated plate of the sound absorbing unit by injection molding in which a direction substantially parallel to the first direction is a mold opening direction or a mold sliding direction; and
manufacturing the sound absorbing unit by closing an opening of the part with the perforated plate.

12. A method for manufacturing the sound absorbing unit according to claim 8, the method comprising:
integrally molding a part other than the other plate member of the sound absorbing unit by injection molding in which a direction substantially parallel to the first direction is a mold opening direction or a mold sliding direction; and
manufacturing the sound absorbing unit by closing an opening of the part with the other plate member.

13. A sound absorbing structure comprising a plurality of sound absorbing units according to claim 1, and wherein
the plurality of sound absorbing units are arranged in a direction substantially perpendicular to the second direction.

14. The sound absorbing structure according to claim 13, wherein the plurality of sound absorbing units are arranged in an orientation where one end of the first cavity in the first direction where the perforated plate is provided is positioned lower than another end of the first cavity in the first direction.

15. The sound absorbing structure according to claim 13, wherein a gap through which air can flow in the second direction is provided between the plurality of sound absorbing units arranged side by side.

16. A computer-implemented design method for the sound absorbing unit according to claim 1, the method comprising:
building a plurality of analysis models of the sound absorbing unit, wherein the analysis models are different from each other in at least one of a diameter of holes present in the perforated plate, a number of holes present in the perforated plate, and size of the cavity existing inside the sound absorbing unit;
evaluating sound absorption characteristics of each of the plurality of built analysis models; and
determining design parameters for the sound absorbing unit based on the evaluation of the sound absorption characteristics.
